(19) United States
(12) Patent Application Publication
(10) Pub. No.: US 2025/0370007 A1
(43) Pub. Date: Dec. 4, 2025

(54) SYSTEM AND METHOD OF STORING AND DISPLAYING MEASUREMENT SIGNALS IN REAL TIME

(71) Applicant: Keysight Technologies, Inc., Santa Rosa, CA (US)

(72) Inventors: Hank H. Shie, Sunnyvale, CA (US); Joel Moens, Santa Rosa, CA (US); Keyne Dirks, Santa Rosa, CA (US); Richard Overdorf, Santa Rosa, CA (US)

(21) Appl. No.: 18/680,627

(22) Filed: May 31, 2024

(51) Int. Cl. G01R 13/02

(52) U.S. Cl. CPC G01R 13/0272; G01R 13/029

(57) ABSTRACT

A system for storing and displaying measurement signals of a spectrum analyzer with RTSA includes a circular buffer having a predetermined buffer length for buffering spectrum digital data in a predetermined order via a first interface, and outputting the buffered digital data in the predetermined order; a storage unit for receiving the buffered digital data output from the circular buffer in real time via a second interface, where the storage unit includes segmented BIN files for storing portions of the received digital data in binary format, where each segmented BIN file is separately retrievable for display during the RTSA measurement; and a controller for allowing the circular buffer to continue buffering the spectrum digital data or stop buffering the spectrum digital data based on whether the buffered digital data are output from the circular buffer faster than the spectrum digital data are written in the circular buffer.

### BACKGROUND

Generally, in the field of system testing and measurements, customers want faster test throughput with better frequency, amplitude and time resolution, at wider bandwidth and longer observation times. To this end, a conventional spectrum analyzer with real time spectrum analysis (RTSA) is a test instrument that provides continuous, gapless, visualization of radio frequency (RF) signals across frequency, amplitude and time domains with as much as 2 GHz intermediate frequency bandwidth (IFBW). However, even technologically advanced RTSAs limit customers to record and transfer up to about 250,000 gapless slices of frequency traces (frequency slices) to an external computer. Further, in conventional systems, storage is limited and measurements must be paused or stopped in order for the record and transfer to take place.

For example, a conventional signal analyzer with RTSA may have a limited storage of frequency slice data (e.g., 800+ frequency and amplitude pairs of data per frequency slice) in software, and a maximum of 250,000 (250k) frequency slices of data. In addition, the 250k frequency slices of data are not accessible via standard commands for programmable instruments (SCPI) queries in the event the user wants to offload the data from the signal analyzer. That is, the customer would first pause or stop the measurement, and then setup and request via SCPI queries to write 250k frequency slices of data to instrument's local drive as a single comma-separated values (CSV) text file. The CSV text file may then be transferred to an external device, such as a remote personal computer (PC), using a universal serial bus (USB) or a local area network (LAN) for further analysis. The requirement to pause/stop the RTSA measurement before data can be written to the instrument's local drive means that the customer cannot continuously capture data while RTSA is running. In addition, the spectrum analyzer has the 250k frequency slices limitation even after the measurement has paused or stopped. Also, CSV text file format is inefficient at storing spectrum data, as compared to potential binary format, for example, thereby creating bottleneck slowdown for offloading the data from the spectrum analyzer to the remote PC.

What is needed, therefore, is a system with the ability to transfer continuously gapless frequency traces, without limit, up to accessible disk storage capacity, which is well beyond the conventional limitation of 250k frequency slices. This would be particularly useful to customers for continuous gap-free data logging, for example.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 is a simplified block diagram of a test system for storing and displaying measurement signals received from a device under test (DUT) in real time, according to a representative embodiment.

FIG. 2 is a simplified block diagram showing a circular buffer, according to a representative embodiment.

FIG. 3 is a table showing estimates of how much spectrum digital data indicated in frequency slices can be captured with various amounts of storage capacity of a storage unit, according to a representative embodiment.

FIG. 4A is a flow diagram illustrating a method of storing and displaying measurement signals received from a DUT in real time, according to a representative embodiment.

FIG. 4B is a continuation of the flow diagram in FIG. 4A illustrating the method of storing and displaying measurement signals received from the DUT in real time, according to a representative embodiment.

FIG. 4C is a continuation of the flow diagram in FIG. 4A illustrating the method of storing and displaying measurement signals received from the DUT in real time, according to a representative embodiment.

FIG. 5 is an illustrative screen shot of BIN files captured with RTSA using a circular buffer, according to a representative embodiment.

FIG. 6 is a simplified block diagram of a representative processing unit, according to a representative embodiment.

### DETAILED DESCRIPTION

In the following detailed description, for purposes of explanation and not limitation, representative embodiments disclosing specific details are set forth in order to provide a thorough understanding of an embodiment according to the present teachings. Descriptions of known systems, devices, materials, methods of operation and methods of manufacture may be omitted so as to avoid obscuring the description of the representative embodiments. Nonetheless, systems, devices, materials and methods that are within the purview of one of ordinary skill in the art are within the scope of the present teachings and may be used in accordance with the representative embodiments. It is to be understood that the terminology used herein is for purposes of describing particular embodiments only and is not intended to be limiting. The defined terms are in addition to the technical and scientific meanings of the defined terms as commonly understood and accepted in the technical field of the present teachings.

It will be understood that, although the terms first, second, third etc. may be used herein to describe various elements or components, these elements or components should not be limited by these terms. These terms are only used to distinguish one element or component from another element or component. Thus, a first element or component discussed below could be termed a second element or component without departing from the teachings of the present disclosure.

The terminology used herein is for purposes of describing particular embodiments only and is not intended to be limiting. As used in the specification and appended claims, the singular forms of terms “a,” “an” and “the” are intended to include both singular and plural forms, unless the context clearly dictates otherwise. Additionally, the terms “comprises,” and/or “comprising,” and/or similar terms when used in this specification, specify the presence of stated features, elements, and/or components, but do not preclude the presence or addition of one or more other features, elements, components, and/or groups thereof. As used herein, the term “and/or” includes any and all combinations of one or more of the associated listed items.

Unless otherwise noted, when an element or component is said to be “connected to,” “coupled to,” or “adjacent to” another element or component, it will be understood that the element or component can be directly connected or coupled to the other element or component, or intervening elements or components may be present. That is, these and similar terms encompass cases where one or more intermediate elements or components may be employed to connect two elements or components. However, when an element or component is said to be “directly connected” to another element or component, this encompasses only cases where the two elements or components are connected to each other without any intermediate or intervening elements or components.

The present disclosure, through one or more of its various aspects, embodiments and/or specific features or sub-components, is thus intended to bring out one or more of the advantages as specifically noted below. For purposes of explanation and not limitation, example embodiments disclosing specific details are set forth in order to provide a thorough understanding of an embodiment according to the present teachings. However, other embodiments consistent with the present disclosure that depart from specific details disclosed herein remain within the scope of the appended claims. Moreover, descriptions of well-known apparatuses and methods may be omitted so as to not obscure the description of the example embodiments. Such methods and apparatuses are within the scope of the present disclosure.

The various embodiments are in the technical field of measuring and testing electrical devices, and are directed to implementation of test instruments, including real time spectrum analysis (RTSA). Generally, according to various embodiments, a system, method and computer readable medium enable a spectrum analyzer with RTSA to save frequency slices (spectrum digital data) of a measurement signal in a circular buffer, and to immediately read out the frequency slices to a storage unit continuously and gap-free until the storage unit is full, while the measurement by the RTSA continues running. Using an illustrative standard hardware configuration, the number of frequency slices stored in the storage unit can exceed two million, for example. The frequency slices are stored in binary (BIN) format, which is more efficient than CSV text format, thereby improving data offload transfer rate and storage efficiency. In addition, new frequency slices are stored in a new BIN file every few seconds, so the user is able to offload already written BIN files, again while the measurement by the RTSA continues running. That is, the frequency slices are stored in the BIN files, making the frequency slices accessible for retrieval.

According to a representative embodiment, a system is provided for storing and displaying measurement signals of a spectrum analyzer with real time spectrum analysis (RTSA) in real time. The system includes an analog to digital converter (ADC), a detector unit, a circular buffer, a storage unit, and a controller. The ADC is configured to sample a measurement signal acquired from a device under test (DUT) during a measurement by the spectrum analyzer, and to output sampled digital data in a data stream in time domain. The detector unit is configured to convert the sampled digital data from the time domain to frequency domain to provide detected spectrum digital data. The circular buffer has a predetermined buffer length, and is configured to receive the spectrum digital data via a first interface, to write the spectrum digital data as buffered digital data in a predetermined order starting at a beginning of the predetermined buffer length until reaching an end of the predetermined buffer length, to output the buffered digital data in the predetermined order, and to overwrite previously buffered digital data in the predetermined order starting at the beginning of the predetermined buffer length after reaching the end of the predetermined buffer length. The storage unit is configured to receive the buffered digital data output from the circular buffer in real time via a second interface, where the storage unit includes multiple segmented BIN files configured to store portions of the received digital data in binary format, respectively, where each segmented BIN file of the multiple segmented BIN files is separately retrievable in real time by a processor for display during the measurement by the RTSA. The controller is configured to determine whether the buffered digital data are output from the circular buffer faster than the spectrum digital data are written in the circular buffer. When the controller determines that the buffered digital data are output from the circular buffer faster than the spectrum digital data are written into the circular buffer, the controller is further configured to enable the circular buffer to continue to write the spectrum digital data in the predetermined order and to output the buffered digital data to the storage unit uninterrupted in real time via the second interface. When the controller determines that the buffered digital data are output from the circular buffer slower than the spectrum digital data are written in the circular buffer, but an entirety of the predetermined length of the circular buffer is able to be output by the circular buffer at least once before the buffered digital data are overwritten, the controller is further configured to control the circular buffer to continue to write the spectrum digital data in the predetermined order until the circular buffer is about to begin overwriting buffered digital data of the previously buffered digital data that has not yet been output to the storage unit.

According to another representative embodiment, a method is provided for storing and displaying measurement signals of a spectrum analyzer with RTSA in real time. The method includes sampling and digitizing a measurement signal received from a DUT to provide sampled digital data in a data stream in time domain; converting the sampled digital data from the time domain to frequency domain to provide detected spectrum digital data; writing the spectrum digital data into a circular buffer via a first interface, where the circular buffer has a predetermined buffer length, where the circular buffer is configured to buffer the spectrum digital data as buffered digital data in a predetermined order starting at a beginning of the predetermined buffer length until reaching an end of the predetermined buffer length, and overwriting previously buffered digital data in the predetermined order starting at the beginning of the predetermined buffer length after reaching the end of the predetermined buffer length; reading the buffered digital data from the circular buffer in real time via a second interface; storing portions of the read digital data in a plurality of segmented BIN files of a storage unit in binary format, respectively; separately retrieving each segmented BIN file of the plurality of segmented BIN files in real time during the measurement by the spectrum analyzer; and determining whether the buffered digital data are output from the circular buffer faster than the spectrum digital data are written in the circular buffer. When the buffered digital data are output from the circular buffer faster than the spectrum digital data are written in the circular buffer, the circular buffer is allowed to continue to write the spectrum digital data in the predetermined order and to store the portions of the read digital data in the storage unit uninterrupted in real time via the second interface. When the buffered digital data are output from the circular buffer slower than the spectrum digital data are written in the circular buffer, but an entirety of the predetermined length of the circular buffer is able to be output by the circular buffer at least once before the buffered digital data are overwritten, continuing the writing of the spectrum digital data until the circular buffer is about to begin overwriting buffered digital data of the previously buffered digital data that has not yet been output to the storage unit.

According to another representative embodiment, a non-transitory computer readable medium stores instructions for storing and displaying measurement signals of a spectrum analyzer with RTSA in real time. When executed by a processing unit, the instructions cause the processing unit to write spectrum digital data in a circular buffer via a first interface, where the spectrum digital data includes digitized data of a measurement signal received from a DUT and converted from time domain to frequency domain, where the circular buffer has a predetermined buffer length, where the circular buffer is configured to write the spectrum digital data as buffered digital data in a predetermined order starting at a beginning of the predetermined buffer length until reaching an end of the predetermined buffer length, and overwrite previously buffered digital data in the predetermined order starting at the beginning of the predetermined buffer length after reaching the end of the predetermined buffer length; read the buffered digital data from the circular buffer in real time via a second interface; store portions of the read digital data in multiple segmented BIN files of a storage unit in binary format, respectively; separately retrieve each segmented BIN file of the multiple segmented BIN files in real time during the measurement by the RTSA; and determine whether the buffered digital data are output from the circular buffer faster than the spectrum digital data are written in the circular buffer. When the buffered digital data are output from the circular buffer faster than the digital data are written in the circular buffer, the instructions allow the circular buffer to continue to write the spectrum digital data in the predetermined order and to store the portions of the read digital data in the storage unit uninterrupted in real time via the second interface. When the buffered digital data are output from the circular buffer slower than the spectrum digital data are written in the circular buffer, but an entirety of the predetermined length of the circular buffer is able to be output by the circular buffer at least once before the buffered digital data are overwritten, the instructions continue the writing of the spectrum digital data until the circular buffer is about to begin overwriting buffered digital data of the previously buffered digital data that has not yet been output to the storage unit.

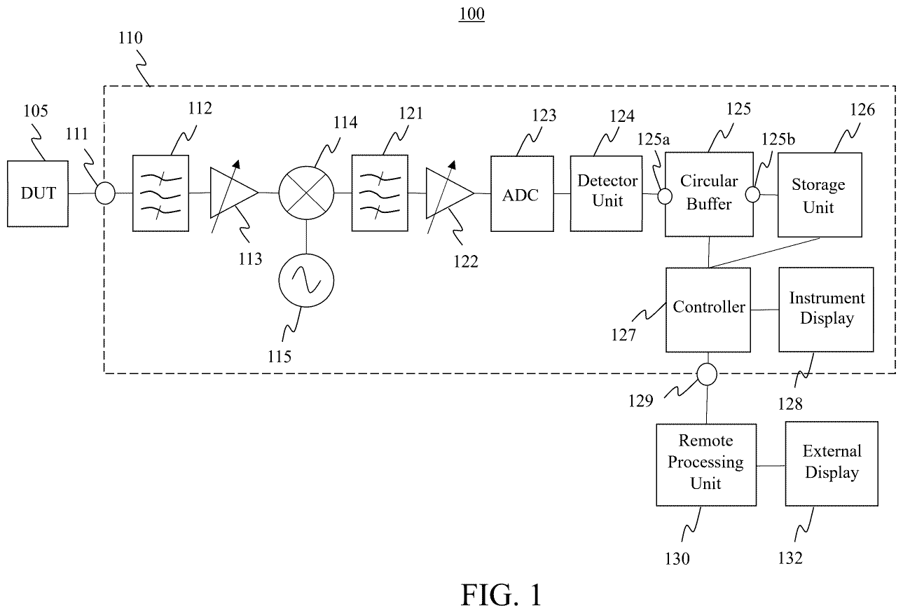

FIG. 1 is a simplified block diagram of a test system for measuring and displaying signals received from a DUT in real-time, according to a representative embodiment.

Referring to FIG. 1, test system 100 includes instrument 110, which may be a signal analyzer with real time spectrum analysis (RTSA). The instrument 110 is configured to receive an RF signal output by DUT 105 for measuring properties of the DUT 105, where the RF signal may be referred to as the signal under test (SUT). The instrument 110 may be other types of test instruments that would benefit from continuous, gap-free storage, such as a signal analyzer, a vector network analyzer (VNA) or oscilloscope, for example, which have RTSA capabilities.

The instrument 110 includes an RF input 111 configured to receive an RF signal output by the DUT 105. The RF signal may be generated by the DUT 105, e.g., when the DUT 105 is an arbitrary waveform generator (AWG) or other signal source, or may be provided by the DUT 105 in response to an input stimulus signal. The instrument 110 also includes an RF signal conditioning portion, indicated by representative RF bandpass filter 112 for filtering the RF signal and RF variable gain amplifier (VGA) 113 for amplifying the filtered RF signal. The RF bandpass filter 112 may comprise one or more surface acoustic wave (SAW) filters, for example. The RF signal conditioning portion may include additional components, such as attenuators and additional filters and/or amplifiers without departing from the scope of the present teachings.

The filtered RF signal is down-converted to an intermediate frequency (IF) signal by a mixer 114, which is configured to mix the amplified RF signal with a local oscillator (LO) signal generated by an LO 115. The instrument 110 further includes an IF signal condition portion, indicated by representative IF bandpass filter 121 for filtering the IF signal and IF VGA 122 for amplifying the filtered IF signal. The IF signal conditioning portion may include additional components, such as attenuators and additional filters and/or amplifiers without departing from the scope of the present teachings.

The amplified IF signal is sampled and digitized by an analog to digital converter (ADC) 123 to provide sampled digital data in a data stream. To the extent the amplified IF signal is not a baseband signal, a numerically controlled oscillator (NCO) (not shown) may down convert and/or shift the amplified IF signal to digital baseband following digitization. The ADC 123 samples and digitizes the amplified IF signal in the time domain. The sampled digital data of the data stream is input to a detector unit 124, which converts the sampled digital data from the time domain to the frequency domain to provide spectrum digital data. The spectrum digital data correspond to frequency slices of the IF signal. The detector unit 124 may perform overlapped windowed fast Fourier transform (FFT) to convert to the frequency domain, and may be implemented using multiple parallel detectors to generate the frequency slices, respectively. In various embodiments, the detector unit 124 may be implemented using one or more of field programmable gate arrays (FPGAs), digital signal processors (DSPs), peak detectors, average detectors, and/or pit detectors, for example, although any components capable of performing conversion from the data steam from the time domain to the frequency domain may be incorporated without departing from the scope of the present teachings. For example, a peak detector receives n frequency slices, and each frequency slice has multiple (e.g., 1024) frequency bins. The peak detector finds the highest value of each frequency bin of the n frequency slices and generates one spectrum slice (spectrum digital data) comprising the n highest values. Similarly, an average detector receives n frequency slices, where each slice has multiple (e.g., 1024) frequency bins. The average detector finds the average value of each frequency bin of the n frequency slices and generates one spectrum slice comprising the n average values.

The instrument 110 further includes a circular buffer 125, which may be a dynamic random-access memory (DRAM), for example. However, other types of memory may be incorporated, such as a solid state drive (SSD) or video random-access memory (VRAM), for example, without departing from the scope of the present teachings. The circular buffer 125 has a predetermined size or capacity, referred to as the buffer length. For example, the buffer length of the circular buffer 125 may be 256 MB to 16 GB, although any compatible buffer length may be incorporated. The circular buffer 125 has a first (write) interface 125a for receiving the spectrum digital data from the detector unit 124, which is written or buffered (temporarily stored) in binary format, and a second (read) interface 125b for outputting buffered digital data to storage unit 126 under control of a controller 127, as discussed below. The second interface 125b converts the output buffered digital data to a binary format used by the storage unit 126. The spectrum digital data may be written into the circular buffer 125 as buffered digital data in accordance with the output rate of the detector unit 124. The output rate of the detector unit 124 may be determined by the user settable acquisition time, which sets acquisition time per spectrum slice of the spectrum digital data. The buffered digital data may be read from the circular buffer 125, where the read rate depends on the speed of the second interface 125b and the ability of the controller 127 to write the buffered digital data into the storage unit 126. The controller 127 may also process and send binary formatted data output from the circular buffer 125 directly to an instrument display 128 via at the second interface 125b for real time display.

The storage unit 126 may be implemented by any number, type and combination of memory, including random access memory (RAM), for example, and may store various types of information described herein. For example, the storage unit 126 may include a hard drive in the instrument 110, a Google drive, network accessible storage (NAS), or a universal serial bus (USB) drive interfacing with the instrument 110, or a hard drive on a personal computer (PC) or other processing unit, indicated by remote processing unit 130, mapped to the hard drive in the instrument 110. Generally, the storage unit 126 may include any number, type and combination of computer readable storage media, such as DRAM, a disk drive, flash memory, registers, a hard disk, a removable disk, tape,, floppy disk, blu-ray disk, a USB drive, or any other form of storage medium known in the art.

The storage unit 126 comprises a tangible storage medium for storing data and/or executable software instructions, and is non-transitory during the time the data and/or software instructions are stored therein. As used herein, the term “non-transitory” is to be interpreted not as an eternal characteristic of a state, but as a characteristic of a state that will last for a period. The term non-transitory specifically disavows fleeting characteristics such as characteristics of a carrier wave or signal or other forms that exist only transitorily in any place at any time. The storage unit 126 may store data, software instructions and/or computer readable code that enable performance of various functions. The storage unit 126 may be secure and/or encrypted, or unsecure and/or unencrypted.

In various embodiments, the storage unit 126 includes multiple segmented BIN files configured to store portions of the digital data output from the circular buffer 125 in the binary format, respectively. The binary format enables storing data faster and more efficiently than text file formats, such as the CSV file format, for example, which significantly improves the data offload transfer rate. New digital data are stored in a new BIN file of the multiple segmented BIN files in the storage unit 126 every few seconds, and each BIN file is separately retrievable in real time by the controller 127 or other processing unit during the measurement being performed by the instrument 110. This enables a remote processing unit 130 to receive the BIN files for processing and display of measurement signals on an external display 132, also in real time if desired, based on retrieved BIN files. The processing and display may be performed by the remote processing unit 130 and the external display 132 while the measurements by the instrument 110 continue, or may be performed later due to the large amounts of stored data available in the storage unit 126. In other words, once the BIN files are generated, they may be accessed immediately and/or they may be stored indefinitely, such that past frequency slices may be retrieved and viewed at a later date.

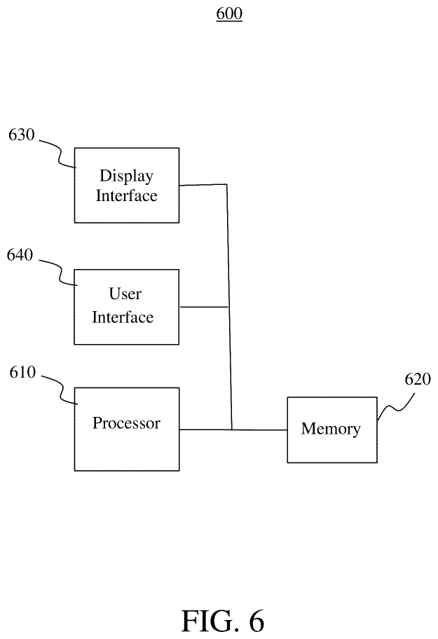

In order to access the BIN files, a script may be provided in a high level programming language, such as MATLAB®, available from The Math Works Inc., or PYTHON®, available from Python Software Foundation, for example. The script may be executed by the controller 127 to process the BIN files and to display the frequency slices (spectrum digital data) from the BIN files in multi-dimensional views on the instrument display 128, or the script may be executed by the remote processing unit 130 to process the BIN files and display the frequency slices on the external display 132, and to apply rudimentary frequency mask trigger (FMT) trigger events, as would be apparent to one skilled in the art. The user may also take advantage of access to a USB drive and/or network drives to allow for even more storage capacity, as discussed below. An illustrative implementation of the controller 127 is described below with reference to FIG. 6.

In an embodiment, the test system 100 also includes the remote processing unit 130 and the external display 132, discussed above. The remote processing unit 139 has access to the controller 127 via interface 129, enabling the remote processing unit 130 to retrieve BIN files from the storage unit 126 under control of the controller 127, where the BIN files may be stored in external memory (not shown) associated with the remote processing unit 130 and/or displayed on the external display 132 by the remote processing unit 130. The interface 129 may be a network interface, such as a USB interface, a wired or wireless LAN interface (e.g., ethernet), a wired or wireless wide area network (WAN) interface, an internet or other packet switching network interface, for example. The remote processing unit 130 may be a workstation, a personal computer (PC), laptop, or other computing device used by the user to receive data (e.g., frequency slices) provided by the instrument 110 when measuring the RF signal output by the DUT 105. An illustrative implementation of the remote processing unit 130 is described below also with reference to FIG. 6.

The remote processing unit 130 retrieves the binary formatted data from the storage unit 126 by communicating with the controller 127, as would be apparent to one skilled in the art. The remote processing unit 130 directs a corresponding external memory (e.g., memory 620) to store portions of the digital data received from of the circular buffer 125 in the binary format, respectively. Like the storage unit 126, the external memory includes multiple segmented BIN files configured to store portions of the digital data received from the circular buffer 125 in the binary format, respectively. New digital data are stored in a new BIN file of the multiple segmented BIN files every few seconds, and each BIN file is separately retrievable in real time, which enables real time processing and display of measurement signals based on retrieved BIN files on the external display 132, while the measurements by the instrument 110 continue. The BIN files likewise are separately retrievable at a later time.

Each of the instrument display 128 and the external display 132 may be a monitor such as a computer monitor, a television, a liquid crystal display (LCD), an organic light emitting diode (OLED), a flat panel display, a solid-state display, or a cathode ray tube (CRT) display, or an electronic whiteboard, for example. The instrument display 128 and/or the external display 132 may also provide a graphical user interface (GUI) for displaying and receiving information to and from the user.

Generally, the circular buffer 125 is configured to buffer (temporarily store) the spectrum digital data output by the detector unit 124 in a predetermined order. The circular buffer 125 starts storing at a first segment at the beginning of the predetermined buffer length until reaching a last segment at the end of the predetermined buffer length, and outputs the buffered digital data from the segments to the storage unit 126 in the order received. The circular buffer 125 thus operates in a first-in first-out (FIFO) configuration. As the detected spectrum digital data continues to arrive, eventually reaching the end of the predetermined buffer length, the circular buffer 125 will wrap-around and begin to overwrite the previously buffered digital data in the same predetermined order, starting over at the beginning of the predetermined buffer length. In an embodiment, when the circular buffer 125 is implemented as a large capacity DRAM, as discussed above, the circular buffer 125 may store up to a maximum of two million frequency slices of the spectrum digital data, for example.

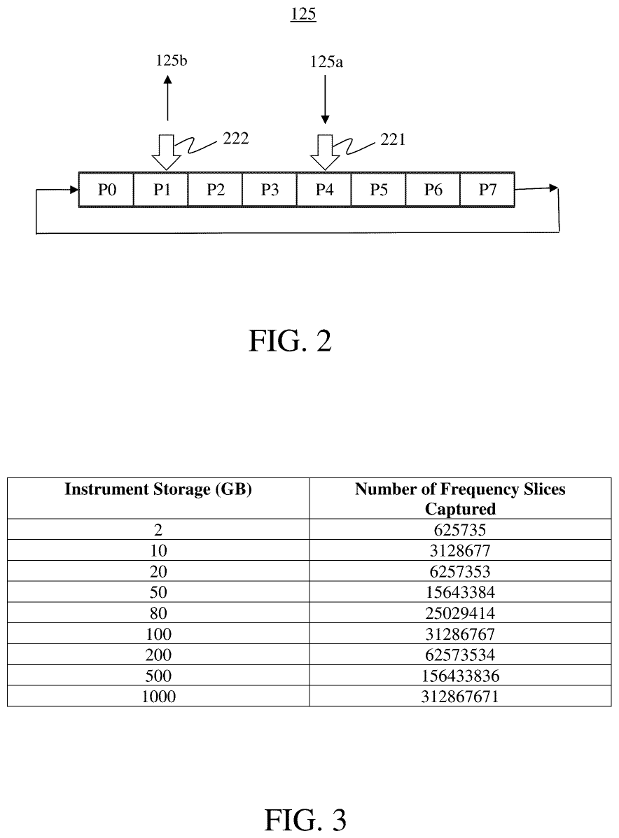

FIG. 2 is a simplified block diagram showing an illustrative circular buffer, according to a representative embodiment. Referring to FIG. 2, the circular buffer 125 is shown with eight segments P0-P7, for purposes of illustration, where each segment may correspond to an arbitrary unit of data, such as some number of bits, bytes, MB, GB, etc. In actuality, the circular buffer 125 may have a total storage capacity (buffer length) of 256 MB to 16 GB, for example, without departing from the scope of the present teachings. The spectrum digital data are consecutively input or read into the illustrative segments P0-P7 of the circular buffer 125 via the first interface 125a, which effectively moves from left to right in the illustrative configuration. The first interface 125a may be a DRAM write interface, for example. In the depicted example, the first interface 125a has advanced to the fifth segment P4, as indicated by write pointer 221. The buffered digital data are consecutively output from the segments P0-P7 of the circular buffer 125 via the second interface 125b, which likewise moves from left to right in the illustrative configuration following the first interface 125a. In the depicted example, the second interface 125b follows the first interface 125a by three segments, and thus has advanced to the second segment P1, as indicated by read pointer 222. The second interface 125b outputs or reads the buffered digital data from the circular buffer 125 to the storage unit 126 in the binary format, as discussed above. The second interface 125b may be a DRAM read interface, for example, that may perform some corrections, e.g., to flatness and amplitude, when storing the read buffered digital data in the storage unit 126.

When the first interface 125a writes digital data in the last segment (P7) at the end of the buffer length, it returns to the first segment (P0), and begins overwriting the previously stored digital data with current digital data. Likewise, when the second interface 125b reads out the BIN data from the last segment (P7) at the end of the buffer length, thus completing a write/read cycle, it returns to the first segment (P0), outputting the newly buffered digital data. The write/read cycles continue, resulting in the digital data to be stored in order in the segmented BIN files of the storage unit 126 in the binary format.

The first and second interfaces 125a and 125b may function at different relative speeds (rates), resulting in three different scenarios with regard to timing of the detected spectrum digital data being written to the circular buffer 125 and the corresponding buffered digital data being read from the circular buffer 125 and stored in the BIN files of the storage unit 126. The controller 127 is configured to determine the relative speeds of the first and second interfaces 125a and 125b, and to implement the corresponding scenario that maximizes storage and retrieval of digital data in real time. The controller 127 may determine the relative speeds by monitoring relative movement of the write pointer 221 and the read pointer 222 in the circular buffer 125, as discussed below.

In a first scenario, the first and second interfaces 125a and 125b are the same speed (i.e., the write rate equals the read rate) or the second interface 125b is faster than the first interface 125a (i.e., the write rate is less than the read rate). In this case, the digital data in all of the segments of the circular buffer 125 will be read from the circular buffer 125 by the second interface 125b and stored in the storage unit 126 before the buffered digital data are overwritten with subsequent spectrum digital data by the first interface 125a. That is, each write/read cycle of the circular buffer 125 is completed before the next cycle begins. In this case, the read pointer 222 may simply point to the same memory location (segment) as the write pointer 221 during operation of the circular buffer 125. As a result, the binary formatted data are stored continuously and gap-free in the storage unit 126 “forever,” meaning until the storage unit 126 is at its maximum storage capacity. Therefore, hours' or days' worth of uninterrupted binary formatted data may be collected.

In a second scenario, the first interface 125a is slightly faster than the second interface 125b (i.e., the write rate is faster than the read rate), enabling completion of at least one complete write/read cycle. In this case, after the at least one complete write/read cycle, the overwriting of the buffered digital data in the circular buffer 125 by first interface 125a eventually catches up to the reading of the buffered digital data by the second interface 125b, resulting in the first interface 125a eventually beginning to overwrite buffered digital data in segments of the circular buffer 125 that the second interface 125b has not yet read out. That is, the write pointer 221 indicating the write location of the first interface 125a effectively “laps” the read pointer 222 indicating the read location of the second interface 125b over time, which creates a circular buffer overflow condition.

As mentioned above, the second scenario occurs after at least one complete write/read cycle of filling all of the segments of the circular buffer 125 with buffered digital data, and reading the buffered digital data from all of the filled segments. The number of completed cycles depends on the relative speeds of the first and second interfaces 125a and 125b. The controller 127 is configured to detect an overflow condition of the circular buffer 125 once the first interface 125a catches up to the second interface 125b, and automatically stops acquisition of the measurement signal from the DUT 105 and writing of the spectrum digital data to the circular buffer 125, which likewise stops the reading of the buffered digital data from the circular buffer 125 to segmented BIN files of the storage unit 126 once the buffered digital data from the remaining buffered digital data is read. In the second scenario, when the circular buffer 125 is implemented by a large capacity DRAM, as mentioned above, for example, the maximum slice count of the frequency slices stored in the storage unit 126 is greater than two million frequency slices, but less than the maximum storage capacity of the storage unit 126.

In a third scenario, the first interface 125a is significantly faster than the second interface 125b (i.e., the write rate is faster than the read rate). In this case, the first interface 125a overwrites all of the previously buffered digital data in the segments of the circular buffer 125 before the second interface 125b is able to read out one complete write/read cycle of the buffered digital data in the storage unit 126. That is, the write pointer 221 indicating the write location of the first interface 125a effectively “laps” the read pointer 222 indicating the read location of the second interface 125b before the second interface 125b is able to empty all of the segments in the circular buffer 125 even once.

The controller 127 is configured to identify the relative difference in writing and reading rates before measurements by the instrument 110 begin, and to determine whether the third scenario exists, as discussed below. For example, the controller 127 may detect the third scenario as part of the setup for the instrument 110 by the user before the instrument 110 starts capture. Accordingly, in the third scenario, the controller 127 sets the circular buffer 125 to operate as a linear (non-circular) buffer, and automatically stops acquisition of the measurement signal from the DUT 105 and writing of the spectrum digital data to the circular buffer 125 as soon as one write/read cycle of the linear buffer is complete. This guarantees one full buffer size of buffered digital data will be stored, but no more. In the third scenario, when the circular buffer 125 is implemented by a large capacity DRAM, as mentioned above, for example, the maximum slice count of the frequency slices stored in the storage unit 126 is less than two million frequency slices, regardless of the maximum storage capacity of the storage unit 126.

Referring again to the first scenario, large amounts of digital data may be buffered and stored in the storage unit 126 for real time processing and display over long periods of time, basically limited only by the maximum amount of storage available in the storage unit 126 (or in the external memory). The controller 127 accordingly prioritizes the first scenario, implementing it whenever possible. As mentioned above, since the instrument 110 is able to perform continuous capture for very long periods of time, it opens up the possibility to apply FMTs or other types of triggers in post processing using post processing software, such as MATLAB® or PYTHON®, for example, without concern of missing signal events or trigger rearm time, or worrying about pre-trigger. The continuous capture is also a much less expensive than conventional IQ streaming solutions, for example.

When the first scenario is not an option due to the write rate of the first interface 125a exceeding and the read rate of the second interface 125b, continuous, gap-free data collection over indefinitely long periods of time is not possible. However, it is still desirable to perform the continuous, gap-free data collection for as long as possible. Therefore, the controller 127 automatically implements the second scenario when the first scenario is unavailable, depending on the relative speeds of the first and second interfaces 125a and 125b, in order to enable large amounts of digital data to be buffered and stored in the storage unit 126 for real time processing and display for as long as possible until the buffered digital data being read from the circular buffer 125 is about to be overtaken by the new spectrum digital data being written to the circular buffer 125. When neither the first nor second scenarios is available, the controller 127 implements the third scenario, applying the circular buffer 125 as a linear buffer, in order to enable real time processing and display of one buffer length of buffered digital data.

FIG. 3 is a table showing estimates of how much spectrum digital data indicated in frequency slices can be captured in the first scenario with various amounts of storage capacity of a storage unit, according to a representative embodiment, where each frequency slice may include 4,096 bytes of data, for example. Referring to FIG. 3, the first column provides the amount of instrument storage, e.g., provided by the storage unit 126, in GB, and the second column provides an estimated number of frequency slices that can be captured and stored in the corresponding amount of instrument storage. So, for example, when the storage unit 126 has 1000 GB of free memory, the user is able to capture continuous, gap-free data of over 312 million frequency slices. Assuming each frequency slice time is 100 μs, capturing 312 million frequency slices would equate to over eight hours of continuous capture.

In order to determine which of the three scenarios to implement, a predetermined threshold of the instrument 110 may be initially determined, which may depend on the speed of the first interface 125a, for example, as established by the acquisition time set by the user. The predetermined threshold may be the speed of the first interface 125a at which it is able to overwrite all of the buffered digital data over the entire buffer length of the circular buffer 125 before the second interface 125b is able to completely empty this same buffered digital data from the circular buffer 125, thereby preventing the circular buffer 125 from completing even one write/read cycle. In other words, when the speed of the first interface 125a is less than the predetermined threshold, it guarantees that at least one complete buffer length worth of digital data being read from the circular buffer and stored in the storage unit 126. As mentioned above, the controller 127 is able to determine the speed at which the first interface 125a is able to overwrite all of the buffered digital data over the entire buffer length of the circular buffer 125 before the second interface 125b is able to completely empty this same buffered digital data as part of the setup for the instrument 110 by the user before the instrument 110 starts capturing data, as discussed above.

The predetermined threshold for the instrument 110 may be determined empirically and systematically by performing measurements of RF signals using different acquisition times set by the user settings for the instrument 110. Acquisition time indicates how fine a time resolution each frequency slice needs to represent. Shorter acquisition time means better time resolution, at the cost of more data being generated. The predetermined threshold depends on access speed of the circular buffer 125, disk storage speed of the storage unit 126, and the operating system, such as Microsoft® Windows® operating system (e.g., Windows 10 or Windows 11), available from Microsoft Corporation, for example.

The predetermined threshold may also depend on additional factors, such as DRAM read and write speed, load on the central processing unit (CPU) of the controller 127, load on the network when remote memory (e.g., of remote processing unit 130) is used, whether the instrument display 128 is on or off during capture, and whether other software program(s) are running on the instrument 110 at the time of capture. In addition, other user settings indirectly affect the predetermined threshold, and may be considered during the empirical and systematic measurements as well, such as PvT slices and histogram plots, for example. When the user chooses to enable such settings for display, part of the DRAM is occupied, thereby requiring more work from the controller 127 and thus slowing down the BIN file writing.

When the speed of the first interface 125a does not exceed the predetermined threshold, the controller 127 executes the first scenario or the second scenario, discussed above, in which multiple buffer lengths of digital data in the circular buffer 125 are stored in the storage unit 126. When the speed of the first interface 125a does exceed the predetermined threshold, the controller 127 executes the third scenario in which only one buffer length of the circular buffer 125 is stored in the storage unit 126. In other words, when the speed of the first interface 125a exceeds the predetermined threshold, the circular buffer 125 is operated as a linear buffer.

In all three scenarios, the controller 127 monitors the relative rates of the first and second interfaces 125a and 125b to account of any changes. For example, a network access speed of the network used for accessing the remote processing unit 130 (e.g., NAS), and/or the write speed of the first interface 125a may slow down, thereby changing the relative write/read speeds of the circular buffer 125. Also, the controller 127 may be configured to directly monitor the circular buffer 125 to determine when the buffered digital data are about to be overwritten by newly written spectrum digital data. For example, the controller 127 may access a write pointer and a read pointer for the circular buffer 125, and compute the delta between the write and read pointers to determine circular buffer overflow condition. The controller 127 determines that the buffered digital data are “about to be overwritten” by newly written spectrum digital data when a predetermined percentage of the circular buffer is left before the write pointer overlaps the read pointer. In various embodiments, the predetermined percentage of remaining circular buffer may be between about 2 percent and about 10 percent of the total buffer, for example. The controller 127 is then able to stop acquisition of the measurement signal from the DUT 105 and writing of the spectrum digital data to the circular buffer 125, as mentioned above. The instrument 110 may include one or more indicators (e.g., on the instrument display 128 or elsewhere) configured to indicate to the user, under control of the controller 127, when the circular buffer 125 will experience an overflow condition and an estimate of how much spectrum digital data can be captured continuously before the overflow condition occurs.

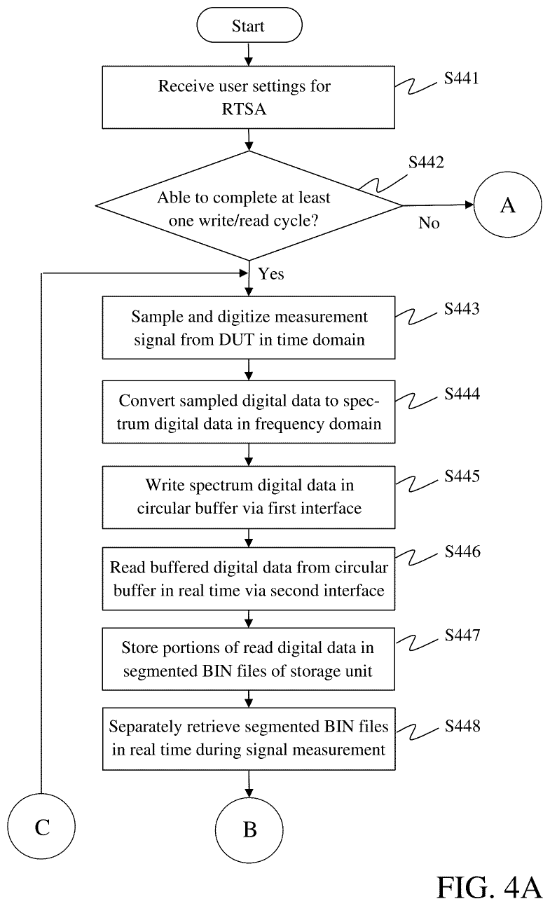

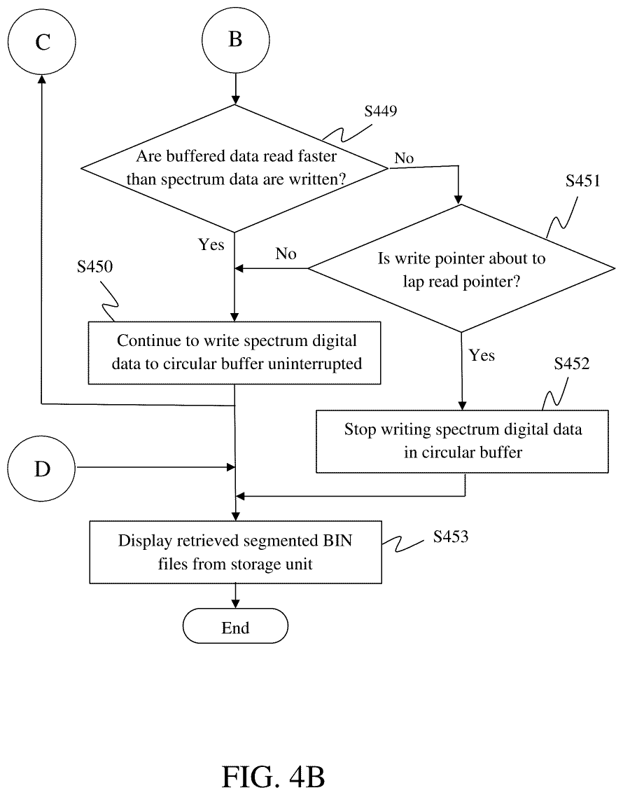

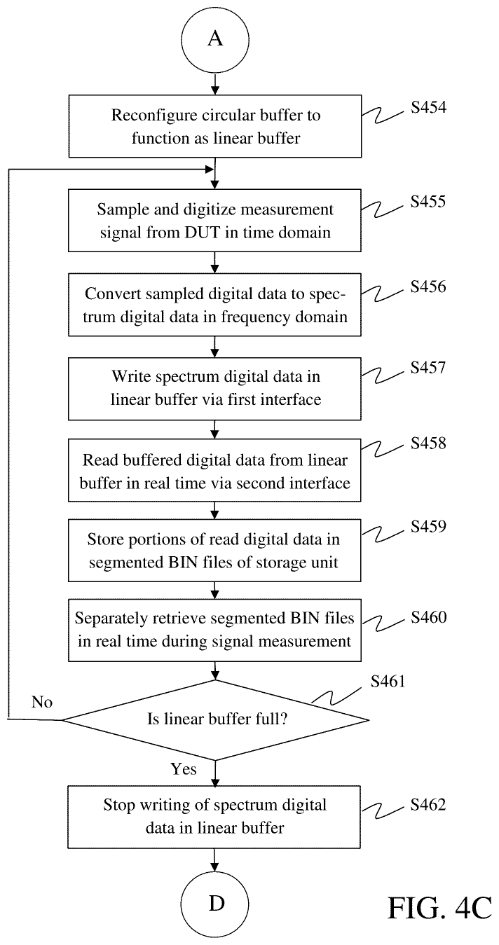

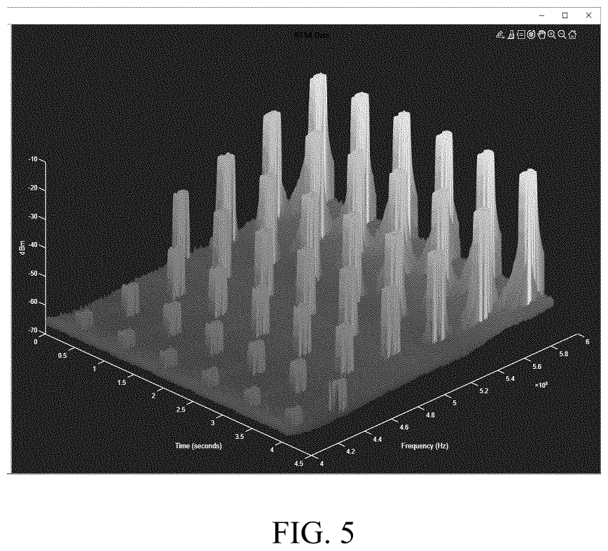

FIGS. 4A, 4B and 4C depict a flow diagram illustrating a method of for measuring and displaying signals received from a DUT in real-time, according to a representative embodiment. The signals from the DUT may be measured by the instrument 110, which may be a spectrum analyzer with RTSA, for example, as depicted in FIG. 1. The steps of FIGS. 4A-4C may be implemented at least in part by the controller 127, the remote processing unit 130, and/or the processing unit 600 depicted in FIGS. 1 and 6, for example, where instructions for performing the various steps are stored on a non-transitory computer readable medium, such as memory of the controller 127 and/or memory 620 depicted in FIG. 6, for example.

Referring to FIG. 4A, settings for performing the RTSA are received in block S441. The settings may be input by a user through a user interface, for example, prior to receiving signals from the DUT. The settings may include spectrum view and acquisition time, for example, where the acquisition time indicates how fine a time resolution each frequency slice needs to represent, as discussed above. Other settings that may affect interface speeds include selection of views to be displayed in addition to the spectrum view, such as the power vs time view and histogram view. In this case, the circular buffer would be split to service the different views, and the total amount of spectrum digital data written to the circular buffer and buffered digital data read from the circular buffer would increase, which reduces write rate and read rate. Different or additional settings may be received without departing from the scope of the present teachings.

In block S442, it is determined whether at least one complete write/read cycle of the circular buffer can be performed based on the user settings. In other words, a determination is made as to whether buffered digital data stored in an entirety of a predetermined length of the circular buffer will be output at least once before the buffered digital data are completely overwritten by subsequent spectrum digital data output by a detector unit.

In an embodiment, the determination may be made by determining the speeds of the first and second interfaces of the circular buffer, respectively; determining a first time required to fill the circular buffer with the spectrum digital data based on the predetermined buffer length of the circular buffer, size of the spectrum digital data, acquisition speed, and the speed of the first interface; determining a second time to read out the buffered digital data from the circular buffer to be stored in the segmented BIN files of the storage unit based on the speed of the second interface; and comparing the second time to the first time to determine whether all buffered digital data in one cycle of the circular buffer can be output to the segmented BIN files before being entirely overwritten. The speeds of the first and second interfaces may be determined empirically and systemically based on factors such as user settings, CPU load, DRAM read and write speed, and network congestion if storage is across a network, for example.

In another embodiment, the determination of whether at least one complete write/read cycle of the circular buffer can be performed may be made using a predetermined threshold. As discussed above, the predetermined threshold may be determined empirically and systematically by performing measurements of RF signals using various different combinations of the user settings. Once the predetermined threshold is set, the speed of the first interface in terms of acquisition time may be compared to it. When the acquisition time of the first interface is less than the predetermined threshold, the buffered digital data are read out from the circular buffer slower than the spectrum digital data are written into the circular buffer, and when the acquisition time of the first interface exceeds the predetermined threshold, the buffered digital data are read out from the circular buffer faster than the spectrum digital data are written into the circular buffer.

When it is determined that at least one complete write/read cycle of the circular buffer cannot be performed, such that at least a portion of buffered digital data will be overwritten before being output from the circular buffer (block S442: No), the process proceeds to block S454 in FIG. 4C where the circular buffer is reconfigured to function as a linear buffer (linear buffer mode), as discussed below. When it is determined that at least one complete write/read cycle of the circular buffer can be performed (block S442: Yes), the process continues on to block S443 to start the RTSA using the circular buffer as a circular buffer (circular buffer mode).

In block S443, a measurement signal received from the DUT is sampled and digitized by an ADC to provide sampled digital data in a data stream in the time domain. The measurement signal initially may be down converted from an RF signal to an IF signal before being digitized.

In block S444, the sampled digital data in the data stream is converted from the time domain to the frequency domain to provide spectrum digital data corresponding to frequency slices. The sampled digital data may be converted to the spectrum digital data by performing an overlapped windowed FFT on the sampled digital data, for example. As discussed above, the FFT may be performed using a detector unit including one or more FPGAs, DSPs, peak detectors, average detectors, and/or pit detectors, for example.

In block S445, the spectrum digital data are written in the circular buffer via a first interface. As discussed above, the circular buffer has a predetermined buffer length which is determined by a predetermined storage capacity for buffering the spectrum digital data. The circular buffer is configured to buffer the spectrum digital data in a predetermined order starting at a beginning of the predetermined buffer length until reaching an end of the predetermined buffer length, and overwriting previously buffered digital data in the predetermined order starting at the beginning of the predetermined buffer length after reaching the end of the predetermined buffer length. The circular buffer may be implemented using a large capacity DRAM, for example.

In block S446, the buffered digital data are read from the circular buffer in real time via a second interface. The circular buffer may be implemented as a FIFO buffer, for example, where the buffered digital data are read from the circular buffer in the same order in which the spectrum digital data were written in the circular buffer.

In block S447, portions of the read digital data from the circular buffer are stored in multiple segmented BIN files of a storage unit in binary format, respectively. Each segmented BIN file of the storage unit stores data from at least one from segment of the circular buffer. In an embodiment, each segmented BIN file stores the same number (N) of frequency slices of the read digital data, where N is greater than 1.

In block S448, each segmented BIN file of the multiple segmented BIN files are separately retrieved in real time during the measurement of the signal from the DUT by the instrument (e.g., a spectrum analyzer with RTSA). Alternatively, the segmented BIN files may be stored and retrieved at a later time by the spectrum analyzer and/or by a remote processing unit.

Referring now to FIG. 4B, in block S449, it is determined whether the buffered digital data are read out from the circular buffer faster than the spectrum digital data are written into the circular buffer. In an embodiment, the determination may be made, for example, by monitoring write and read pointers of the circular buffer while RTSA measurement is running. When the buffered digital data are read out from the circular buffer faster than the spectrum digital data are written into the circular buffer, the read pointer may point to the same memory location as write pointer most of the time, or the relative locations of the read and write points may not change. When the buffered digital data are read out from the circular buffer slower than the spectrum digital data are written into the circular buffer, the write pointer will advance on or catch up to (“lap”) the read pointer over one or more subsequent write/read cycles.

When it is determined that the buffered digital data are output from the circular buffer faster than the spectrum digital data are buffered in the circular buffer (block S449: Yes), the spectrum digital data continues to be written to the circular buffer in the predetermined order via the first interface in block S450, and the buffered digital data continues to be read out from the circular buffer in the predetermined order via the second interface to be stored in the storage unit continuously and uninterrupted in real time via the second interface. The process returns to block S443 in FIG. 4A, where the measurement signal received from the DUT continues to be sampled and digitized to provide sampled digital data. The process then continues with the sampled digital data being converted from the time domain to the frequency domain in block S444, the spectrum digital data being written to the circular buffer via the first interface block S445, and so on. In addition, the segmented BIN files of the storage unit may be retrieved and displayed on a display in real time in block S453. The displaying may take place as the measurements by the instrument continue. If this condition continues, the process will simply continue until storage unit runs out of storage space or the user ends it.

When it is determined that the buffered digital data are output from the circular buffer slower than the spectrum digital data are buffered in the circular buffer (block S449: No), the process proceeds to block S451, where it is determined whether the write pointer of the circular buffer is about to overtake or “lap” the read pointer of the circular buffer. In other words, is the circular buffer going to begin overwriting the previously buffered digital data with new spectrum digital data before the previously buffered digital data are output to the storage unit? As mentioned above, the determination is made that the write pointer is about to overtake the read pointer of the circular buffer when only about 2 percent to about 10 percent of the total buffer is left before the write pointer overtakes the read pointer, for example.

When the write pointer is not about to overtake the read point (block S451: No), the spectrum digital data continues to be written to the circular buffer in the predetermined order via the first interface in block S450, and the buffered digital data continues to be read from the circular buffer in the predetermined order to be stored in the storage unit uninterrupted in real time via the second interface, as discussed above. The process then returns to block S443, as discussed above. In addition, the segmented BIN files of the storage unit may be retrieved and displayed on a display in real time in block S453.

When the write pointer is about to overtake the read pointer of the circular buffer (block S451: Yes), the writing of the spectrum digital data in the circular buffer is stopped in block S452, while the buffered digital data continues to be read from the circular buffer until all of the buffered digital data in circular buffer have been written into BIN files of the storage unit (even after the buffering of the spectrum digital data has stopped). The process then ends. Again, the segmented BIN files of the storage unit may be retrieved and displayed on a display in real time in block S453.

Referring now to FIG. 4C, in response to the determination that at least one complete write/read cycle of the circular buffer cannot be performed, such that at least a portion of buffered digital data will be overwritten before being output from the circular buffer (block S442: No), the circular buffer is reconfigured to function as a linear buffer in block S454. The process proceeds similar to the above discussion with reference to steps S443-S448 in FIG. 4A, except that the spectrum digital data is stored in a linear buffer as opposed to a circular buffer. Therefore, there is no need to track the relative speeds/locations of the write and read pointers.

That is, in block S455, a measurement signal received from the DUT is sampled and digitized by an ADC to provide sampled digital data in a data stream in the time domain. In block S456, the sampled digital data in the data stream is converted from the time domain to the frequency domain to provide spectrum digital data corresponding to frequency slices. In block S457, the spectrum digital data are written in the linear circular buffer via a first interface, which has a predetermined buffer length. The linear buffer is configured to buffer the spectrum digital data in a predetermined order starting at a beginning of the predetermined buffer length until reaching an end of the predetermined buffer length. However, there is no overwriting previously buffered digital data.

In block S458, the buffered digital data are read from the linear buffer in real time via a second interface in the same predetermined order, such that the linear buffer may be implemented as a FIFO buffer, for example. In block S459, portions of the read digital data from the circular buffer are stored in multiple segmented BIN files of the storage unit in binary format, respectively. Each segmented BIN file of the storage unit stores data from at least one from segment of the circular buffer, as discussed above. In block S460, each segmented BIN file of the multiple segmented BIN files are separately retrieved in real time during the measurement of the signal from the DUT by the instrument (e.g., a spectrum analyzer with RTSA). Alternatively, the segmented BIN files may be stored and retrieved at a later time by the spectrum analyzer and/or by a remote processing unit.

Since the circular buffer is operating as a linear mode, a determination is made in block S461 as to whether the linear buffer is full. When the linear buffer is not full (block S461: No), the process returns to block S455, where the measurement signal received from the DUT continues to be sampled and digitized to provide sampled digital data. The process continues with the sampled digital data being converted from the time domain to the frequency domain in block S456, the spectrum digital data being written to the linear buffer via the first interface block S457, and so on. In addition, the segmented BIN files of the storage unit may be retrieved and displayed on a display in real time (not shown). When the linear buffer is full (block S461: Yes), the process continues to block S462 to stop writing the spectrum digital data in the linear buffer. The buffered digital data will continue to be output to the storage unit until all of the digital data in the linear buffer has been stored in segmented BIN files. The process proceeds to block S453 in FIG. 4B, where the segmented BIN files of the storage unit may be retrieved and displayed on a display in real time, as discussed above.

In summary, when an entirety of the predetermined length of the circular buffer cannot be output by the circular buffer at least once before the buffered digital data are overwritten, the circular buffer is reconfigured to buffer the spectrum digital data only once in the predetermined order, starting at the beginning of the predetermined buffer length until reaching the end of the predetermined buffer length. There is no overwriting of the buffered digital data afterwards. In other words, the circular buffer is effectively reconfigured to function as a linear buffer. However, when an entirety of the predetermined length of the circular buffer is able to be output by the circular buffer at least once before the buffered digital data are overwritten, the circular buffer is allowed to continue buffering the spectrum digital data until the circular buffer is about to begin overwriting the previously buffered digital data before the previously buffered digital data are output from the circular buffer. At that point, the circular buffer stops buffering new spectrum digital data. The circular buffer continues to output the buffered digital data and write into the BIN files until all new unread buffered digital data are output from the circular buffer. In either case, an alert is provided (e.g., on the display) indicating that the circular buffer is no longer receiving the spectrum digital data in real time.

FIG. 5 is an illustrative screen shot of BIN files captured with RTSA using a circular buffer, according to a representative embodiment. In particular, the screen shot in FIG. 5 is generated using MATLAB® code that reads in the BIN files in a storage unit populated by a circular buffer, according to a representative embodiment, and displays the frequency slices in a three-dimensional plot with frequency, time, and amplitude axis. The frequency slices as displayed enable the user to see all dimensions simultaneously in a spectrum view, which is possible when all of the spectrum digital data is made available.

FIG. 6 is a simplified block diagram of a representative processor unit, such as the controller 127 and the remote processing unit 130 in FIG. 1, according to a representative embodiment.

Referring to FIG. 6, processing unit 600 includes a processor 610, memory 620 for storing instructions executable by the processor 610 to implement the processes described herein, as well as a display interface 630 and a user interface 640 to enable user interaction.

The processor 610 is representative of one or more processing devices, and is configured to execute software instructions to perform functions as described in the various embodiments herein. The processor 610 may be implemented by a general purpose computer, a central processing unit, a digital signal processor (DSP), a graphics processing unit (GPU), one or more processors, microprocessors or microcontrollers, a state machine, a programmable logic device, FPGAs, application specific integrated circuits (ASICs), or combinations thereof, using any combination of hardware, software, firmware, hard-wired logic circuits, or combinations thereof. The term “processor” encompasses an electronic component able to execute a program or machine executable instructions. References to a processor should be interpreted to include more than one processor or processing core, as in a multi-core processor, and/or parallel processors. Programs have software instructions performed by one or multiple processors that may be within the same computing device or which may be distributed across multiple computing devices.

The memory 620 may include a main memory and/or a static memory, where such memories may communicate with each other and the processor 610 via one or more buses. The memory 620 stores instructions which may be arranged in software/firmware modules and used to implement some or all aspects of methods and processes described herein, including the methods described above with reference to FIG. 4, for example. The memory 620 may be implemented by any number, type and combination of RAM and read-only memory (ROM), for example, and may store various types of information, such as software algorithms, data based models including neural network based models, and computer programs, all of which are executable by the processor 610. The various types of ROM and RAM may include any number, type and combination of computer readable storage media, such as a disk drive, flash memory, an electrically programmable read-only memory (EPROM), an electrically erasable and programmable read only memory (EEPROM), registers, a hard disk, a removable disk, tape, compact disk read only memory (CD-ROM), digital versatile disk (DVD), floppy disk, blu-ray disk, a USB drive, or any other form of storage medium known in the art, as discussed above.

The memory 620 is a tangible, non-transitory storage medium for storing data and executable software instructions, as discussed above. The memory 620 may store software instructions and/or computer readable code that enable performance of various functions. The memory 620 may also serve as external storage for BIN files retrieved by the processor 610 from the storage unit 126, as discussed above. The memory 620 may be secure and/or encrypted, or unsecure and/or unencrypted.

The display interface 630 may include any interface for communicating with a visual display, such as the instrument display 128 and/or the external display 132, to enable information and data output by the processor 610, the memory 620 and/or the user interface 640, discussed below, to be displayed. The displayed information and data may include visualization of the measurement signals in the frequency, amplitude and/or time domains, discussed above.

The user interface 640 may include any interface for providing information and data output by the processor 610, the memory 620 and/or the display interface 630 to the user and/or for receiving information and data input by the user. That is, the user interface 640 enables the user to enter data and to control or manipulate aspects of the processes described herein, and also enables the processor 610 to indicate the effects of the user's control or manipulation. The user interface 640 may connect one or more user interfaces, such as a mouse, a keyboard, a mouse, a trackball, a joystick, a haptic device, a microphone, a video camera, a touchpad, a touchscreen, voice or gesture recognition captured by a microphone or video camera, for example, or any other peripheral or control to permit user feedback from and interaction with the processor 610.

While the invention has been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those having ordinary skill in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to an advantage.

Aspects of the present invention may be embodied as an apparatus, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer executable code embodied thereon.

While representative embodiments are disclosed herein, one of ordinary skill in the art appreciates that many variations that are in accordance with the present teachings are possible and remain within the scope of the appended claim set. The invention therefore is not to be restricted except within the scope of the appended claims.

1. A system for storing and displaying measurement signals of a spectrum analyzer with real time spectrum analysis (RTSA) in real time, the system comprising:
an analog to digital converter (ADC) configured to sample a measurement signal acquired from a device under test (DUT) during a measurement by the RTSA, and to output sampled digital data in a data stream in time domain;
a detector unit configured to convert the sampled digital data from the time domain to frequency domain to provide detected spectrum digital data;
a circular buffer having a predetermined buffer length, wherein the circular buffer is configured to receive the spectrum digital data via a first interface, to write the spectrum digital data as buffered digital data in a predetermined order starting at a beginning of the predetermined buffer length until reaching an end of the predetermined buffer length, to output the buffered digital data in the predetermined order, and to overwrite previously buffered digital data in the predetermined order starting at the beginning of the predetermined buffer length after reaching the end of the predetermined buffer length;
a storage unit configured to receive the buffered digital data output from the circular buffer in real time via a second interface, wherein the storage unit comprises a plurality of segmented BIN files configured to store portions of the received digital data in binary format, respectively, wherein each segmented BIN file of the plurality of segmented BIN files is separately retrievable in real time by a processor for display during the measurement by the RTSA; and
a controller configured to determine whether the buffered digital data are output from the circular buffer faster than the spectrum digital data are written in the circular buffer,
wherein when the controller determines that the buffered digital data are output from the circular buffer faster than the spectrum digital data are written in the circular buffer, the controller is further configured to enable the circular buffer to continue to write the spectrum digital data in the predetermined order and to output the buffered digital data to the storage unit uninterrupted in real time via the second interface, and
wherein when the controller determines that the buffered digital data are output from the circular buffer slower than the spectrum digital data are written in the circular buffer, but an entirety of the predetermined buffer length of the circular buffer is able to be output by the circular buffer at least once before the buffered digital data are overwritten, the controller is further configured to control the circular buffer to continue to write the spectrum digital data in the predetermined order until the circular buffer is about to begin overwriting buffered digital data of the previously buffered digital data that has not yet been output to the storage unit.

2. The system of claim 1, wherein the circular buffer comprises a dynamic random-access memory (DRAM).

3. The system of claim 1, wherein the processor is provided in a remote processing unit coupled with the RTSA.

4. The system of claim 1, wherein the controller is configured to determine whether the buffered digital data are output from the circular buffer faster than the spectrum digital data are written in the circular buffer by monitoring a write pointer indicating where the spectrum digital data are being written in the circular buffer from the detector unit and a read pointer indicating where the buffered digital data are being output from the circular buffer to be stored in the storage unit.

5. The system of claim 4, wherein the controller is configured to detect when the circular buffer is about to begin overwriting the buffer digital data of the previously buffered digital data that has not yet been output from the circular buffer by detecting when only about 2 percent to about 10 percent of the circular buffer is left before the write pointer laps the read pointer.

6. The system of claim 1, wherein the controller is further configured to provide an alert indicating that the circular buffer is no longer writing the spectrum digital data.

7. The system of claim 1, wherein the controller is further configured to:
initially determine whether the buffered digital data will be output from the circular buffer slower than the spectrum digital data will be written in the circular buffer, and that an entirety of the predetermined buffer length of the circular buffer cannot be received by the storage unit at least once before being overwritten,
when it is determined that the buffered digital data will be output from the circular buffer slower than the spectrum digital data will be written in the circular buffer, and the entirety of the predetermined buffer length of the circular buffer cannot be received by the storage unit at least once before being overwritten, reconfigure the circular buffer as a linear buffer to buffer the spectrum digital data once in the predetermined order starting at the beginning of the predetermined buffer length until reaching the end of the predetermined buffer length, without overwriting afterwards, and
provide an alert indicating that the circular buffer is no longer writing the spectrum digital data.

8. The system of claim 7, wherein the controller initially determines whether the buffered digital data will be output from the circular buffer slower than the spectrum digital data will be written in the circular buffer by:
determining speeds of the first and second interfaces;
determining a first time required to fill the circular buffer with the spectrum digital data based on the predetermined buffer length of the circular buffer, a size of the spectrum digital data, and the speed of the first interface;
determining a second time to write the buffered digital data to the storage unit based on the speed of the second interface; and
comparing the second time to the first time to determine whether all buffered digital data in one cycle of the circular buffer can be output to the segmented BIN files before being entirely overwritten.

9. The system of claim 1, further comprising:
a display configured to display selected segmented BIN files of the plurality of segmented BIN files of the storage unit, wherein the selected segmented BIN files are identified via a user interface.

10. The system of claim 9, wherein the display comprises an instrument display of the spectrum analyzer.

11. The system of claim 1, wherein each segmented BIN file of the plurality of segmented BIN files stores a same number N of frequency slices of the received digital data, wherein N is greater than 1.

12. The system of claim 1, wherein the storage unit comprises a hard drive in the spectrum analyzer, a Google drive interfacing with the RTSA, network accessible storage (NAS) interfacing with the spectrum analyzer, a universal serial bus (USB) drive interfacing with the spectrum analyzer, or a hard drive on a personal computer (PC) mapped to the hard drive in the spectrum analyzer.

13. A method of for storing and displaying measurement signals of a spectrum analyzer with real time spectrum analysis (RTSA) in real time, the method comprising:
sampling and digitizing a measurement signal received from a device under test (DUT) to provide sampled digital data in a data stream in time domain;
converting the sampled digital data from the time domain to frequency domain to provide detected spectrum digital data;
writing the spectrum digital data in a circular buffer via a first interface, wherein the circular buffer has a predetermined buffer length, wherein the circular buffer is configured to write the spectrum digital data as buffered digital data in a predetermined order starting at a beginning of the predetermined buffer length until reaching an end of the predetermined buffer length, and overwriting previously buffered digital data in the predetermined order starting at the beginning of the predetermined buffer length after reaching the end of the predetermined buffer length;
reading the buffered digital data from the circular buffer in real time via a second interface;
storing portions of the read digital data in a plurality of segmented BIN files of a storage unit in binary format, respectively;
separately retrieving each segmented BIN file of the plurality of segmented BIN files in real time during the measurement by the RTSA; and
determining whether the buffered digital data are output from the circular buffer faster than the spectrum digital data are written in the circular buffer;
when the buffered digital data are output from the circular buffer faster than the digital data are written in the circular buffer, allowing the circular buffer to continue to write the spectrum digital data in the predetermined order and to store the portions of the read digital data in the storage unit uninterrupted in real time via the second interface, and
when the buffered digital data are output from the circular buffer slower than the spectrum digital data are written in the circular buffer, but an entirety of the predetermined buffer length of the circular buffer is able to be output by the circular buffer at least once before the buffered digital data are overwritten, continuing the writing of the spectrum digital data until the circular buffer is about to begin overwriting buffered digital data of the previously buffered digital data that has not yet been output to the storage unit.

14. The method of claim 13, wherein the circular buffer comprises a dynamic random- access memory (DRAM).

15. The method of claim 13, wherein determining whether the buffered digital data are output from the circular buffer faster than the spectrum digital data are written in the circular buffer comprises monitoring a write pointer indicating where the spectrum digital data are being written in the circular buffer and a read pointer indicating where the buffered digital data are being output from the circular buffer to be stored in the storage unit.

16. The method of claim 15, determining that the circular buffer is about to begin overwriting the buffered digital data of the previously buffered digital data that has not yet been output from the circular buffer when only about 2 percent to about 10 percent of the circular buffer is left before the write pointer laps the read pointer; and
stopping the circular buffer from writing the spectrum digital data in real time when only about 2 percent to about 10 percent of the circular buffer is left before the write pointer laps the read pointer.

17. The method of claim 16, further comprising:
providing an alert indicating that the circular buffer is no longer writing the spectrum digital data.

18. The method of claim 13, further comprising:
initially determining whether the buffered digital data will be output from the circular buffer slower than the spectrum digital data will be written in the circular buffer, and an entirety of the predetermined buffer length of the circular buffer cannot be output by the circular buffer at least once before the buffered digital data are overwritten;
when it is determined that the buffered digital data will be output from the circular buffer slower than the spectrum digital data will be written in the circular buffer, and the entirety of the predetermined buffer length of the circular buffer cannot be received by the storage unit at least once before being overwritten, reconfiguring the circular buffer as a linear buffer to buffer the spectrum digital data once in the predetermined order starting at the beginning of the predetermined buffer length until reaching the end of the predetermined buffer length, without overwriting afterwards; and
providing an alert indicating that the circular buffer is no longer writing the spectrum digital data.

19. The method of claim 18, wherein determining whether the buffered digital data will be output from the circular buffer slower than the spectrum digital data will be written in the circular buffer comprises:
determining speeds of the first and second interfaces;
determining a first time required to fill the circular buffer with the spectrum digital data based on the predetermined buffer length of the circular buffer, a size of the spectrum digital data, and the speed of the first interface;
determining a second time to write the buffered digital data to the storage unit based on the speed of the second interface; and
comparing the second time to the first time to determine whether all buffered digital data in one instance of the circular buffer can be written to the segmented BIN files before being entirely overwritten.

20. A non-transitory computer readable medium that stores instructions for storing and displaying measurement signals of a spectrum analyzer with real time spectrum analysis (RTSA) in real time that, when executed by a processing unit, cause the processing unit to:
write spectrum digital data in a circular buffer via a first interface, wherein the spectrum digital data comprises digitized data of a measurement signal received from a device under test (DUT) converted from time domain to frequency domain, wherein the circular buffer has a predetermined buffer length, wherein the circular buffer is configured to write the spectrum digital data as buffered digital data in a predetermined order starting at a beginning of the predetermined buffer length until reaching an end of the predetermined buffer length, and overwriting previously buffered digital data in the predetermined order starting at the beginning of the predetermined buffer length after reaching the end of the predetermined buffer length;
read the buffered digital data from the circular buffer in real time via a second interface;
storing portions of the read digital data in a plurality of segmented BIN files of a storage unit in binary format, respectively;
separately retrieve each segmented BIN file of the plurality of segmented BIN files in real time during the measurement by the RTSA; and
determine whether the buffered digital data are output from the circular buffer faster than the spectrum digital data are written in the circular buffer;
when the buffered digital data are output from the circular buffer faster than the digital data are written in the circular buffer, allowing the circular buffer to continue to write the spectrum digital data in the predetermined order and to store the portions of the read digital data in the storage unit uninterrupted in real time via the second interface, and
when the buffered digital data are output from the circular buffer slower than the spectrum digital data are written in the circular buffer, but an entirety of the predetermined buffer length of the circular buffer is able to be output by the circular buffer at least once before the buffered digital data are overwritten, continuing the writing of the spectrum digital data until the circular buffer is about to begin overwriting buffered digital data of the previously buffered digital data that has not yet been output to the storage unit.
